(19) United States
(12) Patent Application Publication
(10) Pub. No.: US 2026/0349359 A1
(43) Pub. Date: Nov. 5, 2026

(54) MEASUREMENT APPARATUS, MEASUREMENT METHOD, LITHOGRAPHY APPARATUS, AND ARTICLE MANUFACTURING METHOD

(71) Applicant: CANON KABUSHIKI KAISHA, Tokyo (JP)

(72) Inventors: WATARU YAMAGUCHI, Tochigi (JP); YOSHIKI NAGASAWA, Tochigi (JP); YUYA HIRATA, Tochigi (JP)

(21) Appl. No.: 19/663,517

(22) Filed: Apr. 30, 2026

Related U.S. Application Data
(63) Continuation of application No. PCT/JP2024/038943, filed on Oct. 31, 2024.

(30) Foreign Application Priority Data
Nov. 14, 2023 (JP) 2023-193848

(51) Int. Cl. G03F 9/00

(52) U.S. Cl. CPC G03F 9/7088; G03F 9/7046; G03F 9/7092

(57) ABSTRACT

A measurement apparatus includes an image capturing device configured to capture an image of the mark by using an image capturing element, and a control unit configured to obtain a position of the mark based on a result of first measurement using the image capturing device and a result of second measurement using the image capturing device which is performed after the first measurement. The control unit determines, based on design information of the mark, a first binning condition as a condition concerning binning processing in the first measurement and a second binning condition as a condition concerning binning processing in the second measurement, performs the first measurement upon setting the first binning condition, and performs the second measurement upon setting the second binning condition.

### CROSS-REFERENCE TO RELATED APPLICATIONS

This application is a Continuation of International Patent Application No. PCT/JP2024/038943, filed Oct. 31, 2024 which claims the benefit of Japanese Patent Application No. 2023-193848, filed on Nov. 14, 2023, both of which are hereby incorporated by reference herein in their entirety.

### BACKGROUND

### Field of the Technology

The present disclosure relates to a measurement apparatus, a measurement method, a lithography apparatus, and an article manufacturing method.

### Description of the Related Art

It is important for a lithography apparatus such as an exposure apparatus used in a lithography process to align between a shot region on a substrate and an original plate and overlay different layers on the substrate fast and accurately. In order to shorten the measurement time in alignment, there has been proposed a technique of setting binning processing for an image capturing element and measuring the positions of marks. Japanese Patent Laid-Open No. 2007-142078 describes a technique of setting the binning processing of detecting signals upon grouping several adjacent pixels of the plurality of pixels of an image capturing element into one pixel and sequentially performing image capturing at predetermined intervals in a measurement region wider than a measurement viewing field.

Using a binning function, however, can cause a deterioration in the measurement accuracy of a mark formed on a substrate due to a deterioration in pixel resolution.

### SUMMARY

The present disclosure provides a measurement apparatus advantageous in implementing high measurement accuracy in, for example, mark measurement using a binning function.

According to one aspect of the present disclosure, there is provided a measurement apparatus characterized by comprising an image capturing device configured to capture an image of the mark by using an image capturing element and a control unit configured to obtain a position of the mark based on a result of first measurement using the image capturing device and a result of second measurement using the image capturing device which is performed after the first measurement, wherein the control unit determines, based on design information of the mark, a first binning condition as a condition concerning binning processing in the first measurement and a second binning condition as a condition concerning binning processing in the second measurement, performs the first measurement upon setting the first binning condition, and performs the second measurement upon setting the second binning condition.

Features of the present disclosure will become apparent from the following description of embodiments with reference to the attached drawings.

### BRIEF DESCRIPTION OF THE DRAWINGS

FIG. 1A is a view showing the configuration of a measurement apparatus.

FIG. 1B is a view showing the configuration of an image capturing device.

FIG. 2 is a flowchart of a measurement method according to the first embodiment.

FIG. 3A is a view for explaining binning processing.

FIG. 3B is a view for explaining binning processing.

FIG. 3C is a view for explaining binning processing.

FIG. 4A is a view for explaining measurement processing according to the first embodiment.

FIG. 4B is a view for explaining measurement processing according to the first embodiment.

FIG. 4C is a view for explaining measurement processing according to the first embodiment.

FIG. 4D is a graph for explaining measurement processing according to the first embodiment.

FIG. 5A is a graph showing the relationship between the binning conditions and the signal intensities detected by an image capturing element.

FIG. 5B is a graph showing the relationship between the binning conditions and the signal intensities detected by the image capturing element.

FIG. 6 is a flowchart of a measurement method according to the second embodiment.

FIG. 7A is a view for explaining measurement processing according to the second embodiment.

FIG. 7B is a view for explaining measurement processing according to the second embodiment.

FIG. 8 is a flowchart of a measurement method according to the third embodiment.

FIG. 9 is a view for explaining measurement processing according to the third embodiment.

FIG. 10 is a flowchart of a measurement method according to the fourth embodiment.

FIG. 11 is a view showing the configuration of an exposure apparatus according to the fifth embodiment.

FIG. 12 is a flowchart of an exposure method according to the fifth embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

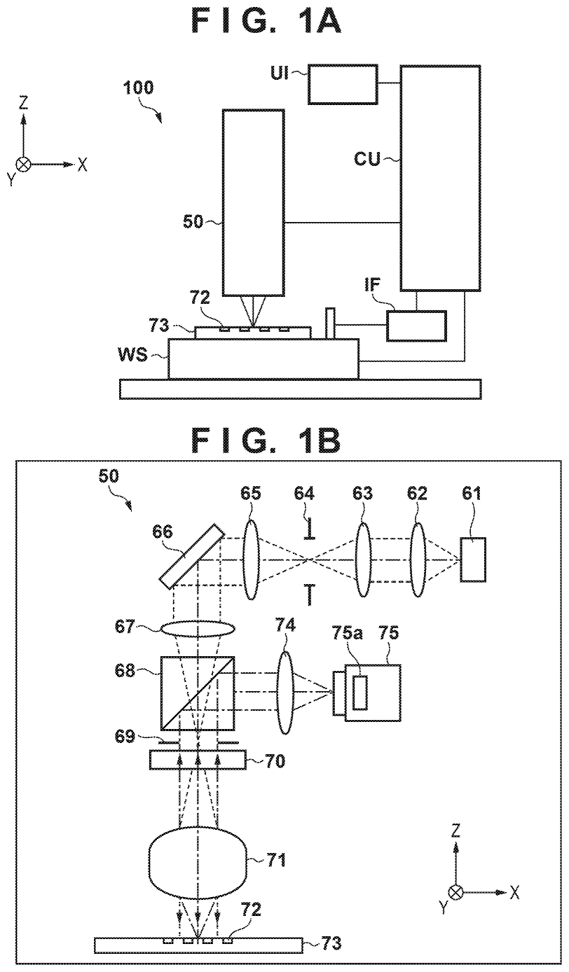

FIG. 1A shows the configuration of a measurement apparatus 100 according to an embodiment. The measurement apparatus 100 is configured to measure the position of a mark provided on a substrate 73. The measurement apparatus 100 includes a substrate stage WS that holds the substrate 73, an image capturing device 50, a control unit CU, and a user interface UI. Here, the substrate 73 is, for example, a substrate used to manufacture a device, such as a semiconductor device or a liquid crystal display device. More specifically, the substrate 73 is a wafer, a glass substrate, or another substrate to be processed.

The substrate stage WS holds the substrate 73 via a substrate chuck (not shown). The substrate stage WS is connected to a stage driving mechanism (not shown). The stage driving mechanism is a positioning mechanism that includes a linear motor or the like and positions the substrate 73 held on the substrate stage WS by driving the substrate stage WS in the X-axis direction, the Y-axis direction, the Z-axis direction, and the rotation directions around the respective axes. The position of the substrate stage WS is monitored by, for example, a 6-axis laser interferometer IF, and the substrate stage WS is driven to a predetermined position under the control of the control unit CU.

The control unit CU is formed by, for example, a computer (information processing apparatus) including a CPU, a memory, and the like, and comprehensively controls the respective units of the measurement apparatus 100 in accordance with a program stored in the storage unit. The control unit CU also functions as a processing unit that obtains the position of a mark 72 (measurement mark) formed on the substrate 73 by performing various types of correction processing (arithmetic processing) with respect to the measurement result obtained by the image capturing device 50, more specifically, the result of image capturing with respect to the mark 72.

The user interface UI can include a display device, an input device, and the like. The user can designate, via the user interface UI, the position of a shot region or a mark in the shot region, which is set to the measurement target, with respect to a plurality of shot regions on the substrate 73.

With reference to FIG. 1B, the configuration of the image capturing device 50 will be described. The image capturing device 50 includes an illumination optical system that illuminates the substrate 73 using light from a light source 61, and an imaging optical system that forms, on an image capturing element 75, an image of the mark 72 formed on the substrate 73. Light from the light source 61 is guided to an illumination aperture stop 64 via lenses 62 and 63. The light having passed through the illumination aperture stop 64 is guided to a polarization beam splitter 68 via a lens 65, a mirror 66, and a lens 67. The P-polarized light transmitted through the beam split plane of the polarization beam splitter 68 passes through an aperture stop 69. After that, the light is converted into circularly polarized light by a λ/4 plate 70 and Koehler-illuminates, via an objective lens 71 arranged such that the optical axis extends along the Z direction, the measurement mark 72 formed on the substrate 73.

The light that is Koehler-illuminated and reflected, diffracted, and scattered by the measurement mark 72 passes through the objective lens 71 and the λ/4 plate 70, and is guided to the aperture stop 69. Here, the polarization state of the light from the mark 72 becomes circular polarization that is reverse to the circular polarization of the light which Koehler-illuminates the mark 72. When the light passes through the λ/4 plate 70, the light is converted from the circularly polarized light to the S-polarized light. After passing through the aperture stop 69, the S-polarized light is reflected on the beam split plane of the polarization beam splitter 68, and guided to the image capturing element 75 via a lens 74. The image capturing element 75 has a signal readout unit 75a that reads out received light as an electrical signal. The signal readout unit 75a is configured to be able to perform the processing (binning processing) of reading out signals upon grouping a plurality of adjacent pixels at the time of readout. Performing binning processing can reduce both the accumulation time due to an increase in charge capacity and the readout time of charge.

Note that the illumination optical system may be provided with a light amount adjustment unit (not shown) and a wavelength adjustment unit (not shown). The light amount adjustment unit adjusts the amount of light illuminating a substrate. For example, when a plurality of ND filters, which have different transmittances to the light from the light source 61, are arranged so as to be switchable, and the light amount adjustment unit controls switching of the ND filters, the intensity of light illuminating the substrate 73 can be adjusted. Further, when a plurality of wavelength filters, which transmit light beams having different wavelength characteristics of the light from the light source 61, are arranged so as to be switchable, and the wavelength adjustment unit controls switching of the wavelength filters, the wavelength of light illuminating the substrate 73 can be adjusted. The wavelength adjustment unit can further include a wavelength variable element and a driving mechanism that drives the wavelength variable element. The driving mechanism includes a linear motor or the like, and can adjust the wavelength of light illuminating the measurement mark 72 by driving the wavelength variable element along a predetermined direction.

The control unit CU in FIG. 1A acquires the position of the mark 72 based on position information of the substrate stage WS obtained by the laser interferometer IF, and a signal waveform obtained by detecting the image of the mark 72. The intensity of the signal waveform can be adjusted by at least any of the following: controlling the light amount adjustment unit (ND filter) provided in the illumination optical system of the image capturing device 50, controlling the output of the light source 61, and controlling the accumulation time of the image capturing element 75.

Note that in the imaging optical system of the image capturing device 50, a detection aperture stop may be formed by arranging a plurality of lenses between the polarization beam splitter 68 and the image capturing element 75. Alternatively, a plurality of aperture stops which enable setting of different numerical apertures with respect to the illumination optical system and the imaging optical system may be provided in each of the illumination aperture stop 64 and the detection aperture stop, and the plurality of aperture stops may be switchable. With this, it is possible to adjust the σ value which is a coefficient representing the ratio of the numerical aperture of the illumination system and the numerical aperture of the imaging system. As a method of detecting the light from the measurement mark 72, for example, dark field detection may be used in which the aperture diameters of the illumination aperture stop 64 and the detection stop are controlled to block the 0th-order diffracted light from the measurement mark 72, thereby detecting only higher-order diffracted light and scattered light.

The following is a description of a method of measuring the position of the substrate 73 fast and accurately by detecting light from a mark formed on the substrate 73 using the measurement apparatus 100 described with reference to FIGS. 1A and 1B.

In the present embodiment, the control unit CU performs the processing of obtaining the position of the mark 72 based on the results of the first measurement using the image capturing device 50 and the second measurement using the image capturing device 50 which is performed after the first measurement.

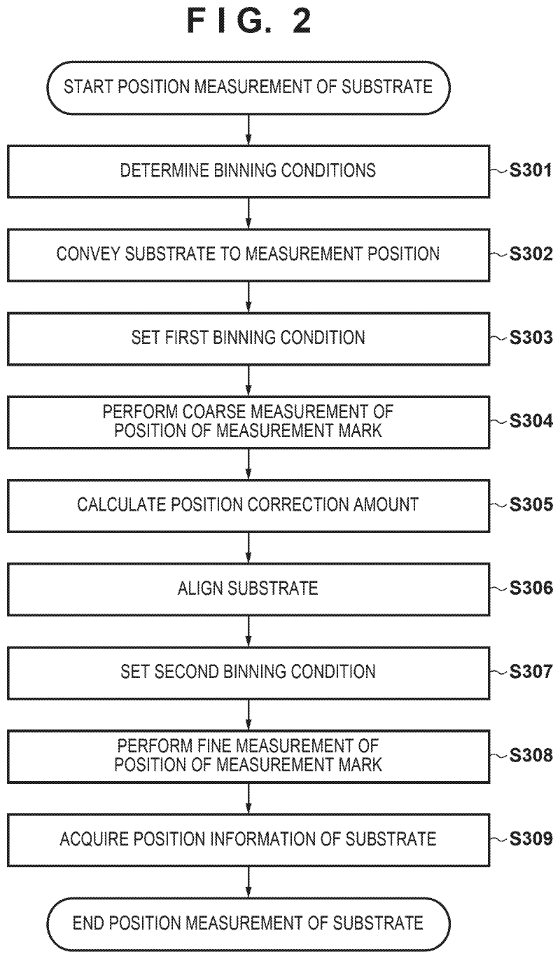

FIG. 2 is a flowchart showing a measurement method according to the first embodiment. The control unit CU executes the measurement method (measurement processing) by comprehensively controlling the respective units of the measurement apparatus 100.

In step S301, the control unit CU determines a condition (the first binning condition) concerning binning processing in the first measurement and a condition (the second binning condition) concerning binning processing in the second measurement based on the design information of the mark 72. In the present embodiment, the first measurement is coarse measurement for obtaining the relative positional shift of the substrate 73 with respect to the image capturing device 50, and the second measurement is fine measurement for accurately obtaining the position of the mark. Binning processing and the method of determining conditions concerning the binning processing will be described in detail later.

In step S302, the control unit CU conveys the substrate 73 into the measurement viewing field of the image capturing device 50 by controlling the substrate stage WS.

In step S303, the control unit CU sets the first binning condition determined in step S301 with respect to the image capturing element 75.

In step S304, the control unit CU controls the image capturing device 50 to capture an image of the mark 72 formed on the substrate 73 for the purpose of coarse measurement of the relative positional shift of the substrate 73 with respect to the image capturing device 50.

In step S305, the control unit CU performs image processing (signal processing and arithmetic processing) for the image of the mark 72 obtained by image capturing in step S304. This will calculate the relative positions between the substrate 73 and the image capturing device 50 and calculate a position correction amount for the alignment between the relative positions.

In step S306, the control unit CU executes relative alignment of the substrate 73 with respect to the image capturing device 50. The alignment of the substrate 73 is executed such that, for example, the X direction in which the substrate stage WS can be driven coincides with the array direction of a plurality of shot regions on the substrate 73 which are exposed to light in the X direction. Alternatively, the alignment of the substrate 73 may be performed such that the image of the mark 72 is arranged in the measurement region of the image capturing device 50 in the second measurement. Alternatively, the alignment of the substrate 73 is not limited to the X direction or the Y direction and may also be executed in the Z direction. For example, coarse measurement is performed to obtain a relative positional shift in the Z direction in the first measurement, and the alignment of the substrate 73 in the Z direction may be performed to arrange the image of the mark 72 at the focal position of the image capturing device 50 in the second measurement based on the result of the first measurement.

In step S307, the control unit CU sets the second binning condition determined in step S301 with respect to the image capturing element 75.

In step S308, the control unit CU controls the image capturing device 50 to capture an image of the mark 72 on the substrate 73 for the purpose of accurately obtaining the position of the mark.

In step S309, the control unit CU performs image processing (signal processing and arithmetic processing) for the image of the mark 72 obtained by image capturing in step S308. This will acquire the position information of the substrate 73 with respect to the image capturing device 50. The position information of the substrate 73 may be acquired by measuring the positions of the plurality of marks 72 formed at different positions on the substrate 73.

In calculating the position of the mark 72 in step S305 or S309 in FIG. 2, the position of the mark 72 can be calculated by processing the image of the mark 72 acquired in step S304 or S308 by using, for example, a template matching method. In the template matching method, performing correlation arithmetic processing between the signals acquired in steps S304 and S308 and a model signal (template) acquired in advance makes it possible to detect a position exhibiting the highest correlation as the central position of the measurement pattern. In general, a model signal (template) is expressed by the relation between the number of pixels and a signal intensity. Obtaining the center-of-gravity position of a region having several pixels on the right and left sides from the position of a peak in a correlation value function can implement a resolution of 1/10 pixel to 1/50 pixel.

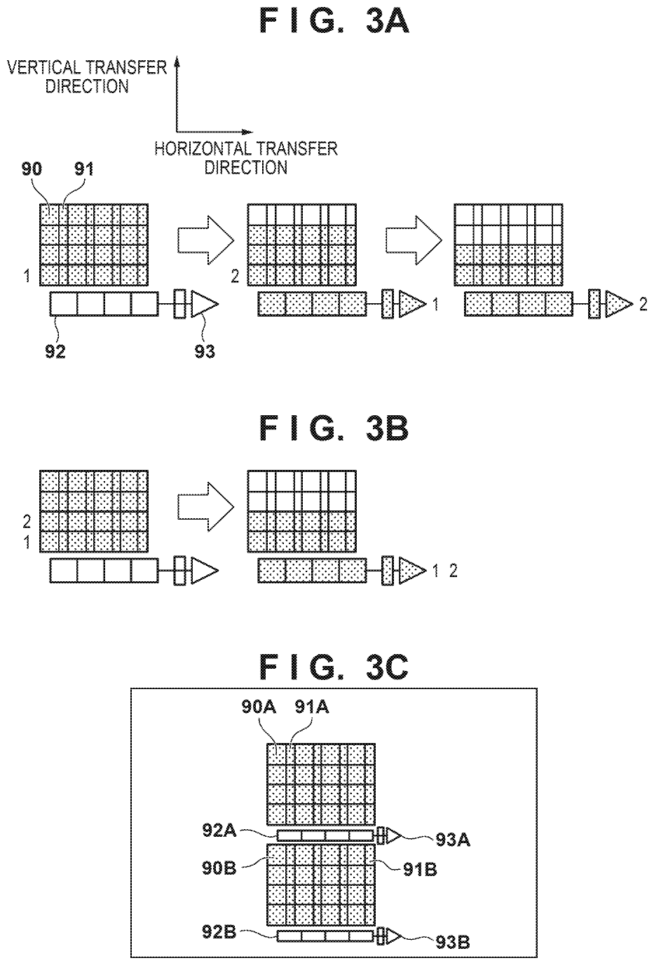

Binning processing in the image capturing element 75 will be described with reference to FIGS. 3A to 3C. FIGS. 3A and 3B are block diagrams showing a configuration example of the signal readout unit 75a in the image capturing element 75. For the sake of simplicity, a 4×4 matrix is used. The image capturing element 75 is an image sensor that acquires image information by transferring and reading out the charge accumulated in a pixel 90. As charge transfer schemes, an inline transfer type and a frame transfer type are known. The following will exemplify the frame transfer type signal readout unit 75a. The frame transfer type signal readout unit 75a can include a vertical shift register 91, a horizontal shift register 92, and a readout amplifier 93. The vertical shift register 91 transfers the charge accumulated in the pixel 90 in the vertical direction. The horizontal shift register 92 sequentially transfers the charge in the horizontal direction. The readout amplifier 93 then reads out a signal. First of all, the charge accumulated below the gate electrode of each pixel of the image sensor is transferred fast to the vertical shift register 91. The vertical shift register 91 then sequentially transfers the charge in the vertical direction. Assume that the respective pixels of the vertical shift register 91 are on the first row, the second row, the third row, and the fourth row. At the time of transfer, the charge in the pixels on the fourth row is simultaneously transferred to the pixels on the third row, the charge in the pixels on the third row is simultaneously transferred to the pixels on the second row, the charge in the pixels on the second row is simultaneously transferred to the pixels on the first row, and the charge in the pixels on the first row is simultaneously transferred to the horizontal shift register 92.

As shown in FIG. 3A, in normal charge readout, every time the charge in a pixel is transferred to the horizontal shift register 92, the readout amplifier 93 operates to read out data in the horizontal shift register 92 one by one. When all the data are read out, the transfer of charge in each pixel is performed again. That is, the charge in the pixels on the third row is simultaneously transferred to the pixels on the second row, the charge in the pixels on the second row is simultaneously transferred to the pixels on the first row, and the charge in the pixels on the first row is simultaneously transferred to the horizontal shift register 92. Likewise, the readout amplifier 93 reads out data in the horizontal shift register 92 and further repeats charge transfer. When all the charge accumulated at first in each pixel is transferred and read out in this manner, one frame readout is finished.

As shown in FIG. 3B, binning processing in the vertical transfer direction can be performed by reading out data in the horizontal shift register 92 after charge transfer is performed several times instead of reading out data every time charge transfer is performed once. For example, the charge in the pixels on the fourth row is simultaneously transferred to the pixels on the third row, the charge in the pixels on the third row is simultaneously transferred to the pixels on the second row, the charge in the pixels on the second row is simultaneously transferred to the pixels on the first row, and the charge in the pixels on the first row is simultaneously transferred to the horizontal shift register 92. Thereafter, the next vertical transfer is started without readout of data in the horizontal shift register 92. That is, the charge in the pixels on the third row, the charge in the pixels on the second row, and the charge in the pixels on the first row are simultaneously and respectively transferred to the pixels on the second row, the pixels on the first row, and the horizontal shift register 92. Thereafter, reading out the data in the horizontal shift register 92 will read out the charge in the pixels on the first row and the charge in the pixels on the second row upon addition. Reading out the photoelectric signals in this manner is equivalent to using, as one line image sensor, an image sensor pixel group corresponding to the pixels on the first row and an image sensor pixel group corresponding to the pixels on the second row.

As described above, binning processing can be implemented by the processing of adding and reading out the charge in a plurality of pixels. It is possible to set a plurality of light-receiving portions, each configured to independently perform signal readout, for one area image sensor by binning processing. Although the method of performing binning processing in the vertical transfer direction has been described so far, the application range of the present disclosure is not limited to the method. For example, controlling the readout amplifier 93 that reads out data in the horizontal shift register 92 can perform binning processing in the horizontal transfer direction. In addition, the signal readout unit 75a in the image capturing element 75 may be configured to include a plurality of vertical shift registers, a plurality of horizontal shift registers, and a plurality of readout amplifiers. In the case shown in FIG. 3C, a vertical shift register 91A, a horizontal shift register 92A, and a readout amplifier 93A are configured for a pixel group 90A, and a vertical shift register 91B, a horizontal shift register 92B, and a readout amplifier 93B are configured for a pixel group 90B. For example, different binning processes may be executed in the detection surface of the image capturing element by setting different binning processes in a plurality of vertical shift registers and a plurality of horizontal shift registers.

In general, known methods of reducing the measurement time in an image capturing element include a method of readout while decimating pixels in the detection surface and a method of readout of only a region of interest in the detection surface. These methods can shorten the charge readout time but cannot shorten the accumulation time. Binning processing is advantageous in shortening the measurement time by shortening both the accumulation time due to an increase in charge capacity and the charge readout time.

Although the configuration for executing binning processing in the image capturing element has been described so far, the application range of the present disclosure is not limited thereto. For example, the control unit CU can execute binning processing for output data from the image capturing element. This makes it possible to reduce the ratio of noise to signal intensity by averaging the electrical noise generated in each pixel of the image capturing element.

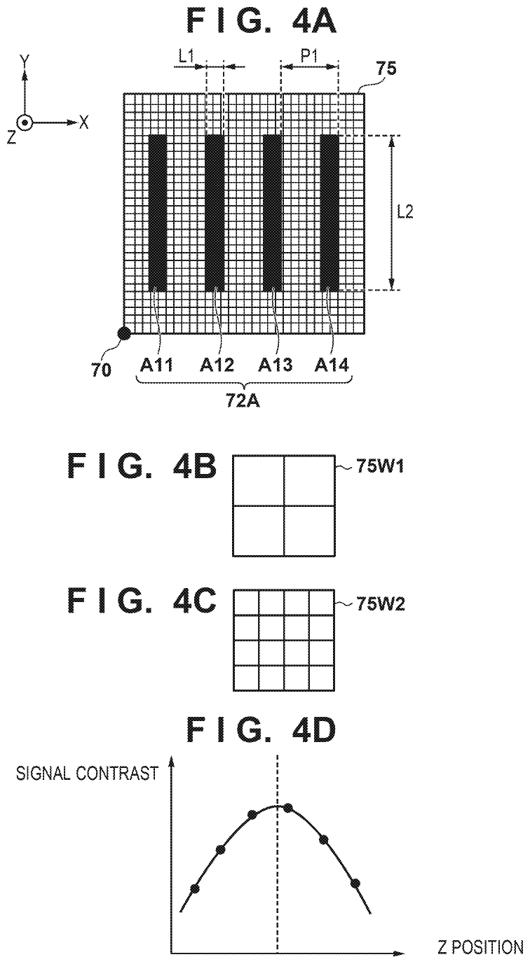

A method of determining binning conditions will be described with reference to FIGS. 4A to 4D. FIG. 4A shows a mark image 72A formed on the detection surface of the image capturing element 75. The image capturing element 75 can be, for example, a two-dimensional image capturing element having a plurality of pixels in the X direction and the Y direction. In this case, the Y direction (first direction) corresponds to the vertical transfer direction of the image capturing element 75, and the X direction (second direction) corresponds to the horizontal transfer direction of the image capturing element 75. The mark image 72A includes a plurality of line elements extending in the Y direction corresponding to the vertical transfer direction of the image capturing element 75. A plurality of line elements are arrayed at a predetermined pitch in the X direction corresponding to the horizontal transfer direction of the image capturing element 75. In the case shown FIG. 4A, a plurality of line elements (mark pattern) can include four line elements A11, A12, A13, and A14. The linewidth (the length in the Y direction) of each line element is represented by L1, the pitch is represented by P1, and the length in the Y direction corresponding to the vertical transfer direction of the image capturing element 75 is represented by L2. The design information of a mark can include information concerning the linewidth L1 of each line element, the pitch P1 between line elements, and the length L2 of each line element in the Y direction.

In measuring the position of a mark in the present embodiment, a substrate is aligned by obtaining the position correction amount of the substrate conveyed to the measurement position by coarse measurement, and fine measurement is then performed. This will accurately measure the position of the mark and acquire the position information of the substrate. Accordingly, for example, a wide measurement viewing field is required for coarse measurement, and a high resolution is required for fine measurement. Assume that measurement is performed so as to satisfy both requirements for a wide measurement viewing field and a high resolution. In this case, charge is read out from many pixels in the image capturing element 75, and hence it takes much time to perform readout. In addition, in order to detect a signal intensity from the mark with high resolution, increasing the accumulation time of the image capturing element for the purpose of obtaining a predetermined detection light amount in each pixel will increase the measurement time.

Accordingly, in the present embodiment, the control unit CU determines the first binning condition set in the first measurement (in the present embodiment, coarse measurement for obtaining the relative positional shift of the substrate 73 with respect to the image capturing device 50) and the second binning condition set in the second measurement (in the present embodiment, fine measurement for accurately obtaining the position of the mark 72) based on the design information of the mark 72 (S301).

FIGS. 4B and 4C show examples of resolutions 75W1 and 75W2 of the image capturing element 75 in a case where the first binning condition and the second binning condition are respectively set in coarse measurement and fine measurement in the present embodiment. As described above, in binning processing, charge accumulated in a plurality of pixels adjacent each other subjected to binning in the image capturing element 75 is added and processed. In the present embodiment, the first binning condition and the second binning condition each can include a binning coefficient indicating the number of adjacent pixels subjected to binning. If, for example, the binning coefficient is 4, it indicates that the number of adjacent pixels subjected to binning is 4. If, for example, the binning coefficient is 9, it indicates that the number of adjacent pixels subjected to binning is 9.

In addition, binning coefficients may include the first binning coefficient concerning binning in the first direction and the second binning coefficient concerning binning in the second direction. More specifically, the first binning coefficient indicates the number of adjacent pixels subjected to binning in the Y direction (first direction) corresponding to the vertical transfer direction of the image capturing element 75. The second binning coefficient indicates the number of adjacent pixels subjected to binning in the X direction (second direction) corresponding to the horizontal transfer direction of the image capturing element 75. In the first measurement and the second measurement, the first binning coefficient and the second binning coefficient can be independently set. In coarse measurement as the first measurement shown in FIGS. 4B, 2 pixel×2 pixel binning processing is set. In this case, both the first binning coefficient and the second binning coefficient are set to 2. In contrast to this, in fine measurement as the second measurement shown in FIGS. 4C, 1 pixel×1 pixel binning processing is set. In this case, “1 pixel×1 pixel binning processing” means that binning processing is not set (binning is invalidated). In this case, both the first binning coefficient and the second binning coefficient are set to 1. As described above, a “binning condition” includes that binning processing is not performed.

As described above, according to the present embodiment, the control unit CU determines the first binning condition and the second binning condition such that the binning coefficient designated by the first binning condition is larger than the binning coefficient designated by the second binning condition. According to such processing, in the coarse measurement shown in FIG. 4B, as compared with the fine measurement shown in FIG. 4C, measurement is performed with a lower resolution while the same measurement viewing field is maintained. Accordingly, in coarse measurement, the measurement time can be shortened by shortening the readout time with a reduction in the number of pixels from which charge is read out and reducing the accumulation time by the addition of charge.

A binning coefficient can be determined so as to reduce the resolution of the image capturing element 75 concerning the linewidth L1 of each line element constituting the mark image 72A, the pitch P1 between the line elements, and the length L2 of each line element in the Y direction in which it extends on the detection surface of the image capturing element 75. Letting Ps be the pixel size of the image capturing element 75 and N be a binning coefficient, the binning coefficient N can be determined so as to satisfy, for example, inequalities (1) to (3) given below:

N≤L1/Ps (1)

N≤P1/Ps (2)

N≤L2/Ps (3)

As described above, since the first binning coefficient and the second binning coefficient can be independently set, the first binning coefficient and the second binning coefficient may be set to different values instead of the same value. Let Ny be the first binning coefficient indicating the number of adjacent pixels subjected to binning in the Y direction and Nx be the second binning coefficient indicating the number of adjacent pixels subjected to binning in the X direction. In this case, the first binning coefficient Ny and the second binning coefficient Nx can be determined with respect to the mark shown in FIG. 4A so as to satisfy inequalities (4) to (6) given below:

Nx≤L1/Ps (4)

Nx≤P1/Ps (5)

Ny≤L2/Ps (6)

In addition, let Pi be the maximum signal intensity that can be detected by the image capturing element 75 and Si be the signal intensity that enables the mark 72 to be measured with desired accuracy (required accuracy). In this case, the binning count N is preferably determined so as to satisfy inequality (7) given below in addition to inequalities (1) to (3) or (4) to (6):

N≤Pi/Si (7)

This makes it possible to prevent the signal intensity obtained by addition by binning processing from exceeding the maximum signal intensity of the image capturing element 75.

FIG. 4D shows a specific example of obtaining the focal position of the image capturing device 50 in the Z direction and the relative positional shift of the substrate 73. The abscissa represents the Z position, and the ordinate represents the signal contrast calculated based on the signal intensity. For example, letting Smax be the maximum value of the signal intensity of the mark image 72A detected by the image capturing device 50 and Smin be the minimum value of the signal intensity, a signal contrast SC is represented by equation (8) given below:

SC=(Smax−Smin)/(Smax+Smin) (8)

With this operation, for example, the Z position at which the signal contrast is maximized may be obtained as the best focus position of the image capturing device 50 by detecting signal contrasts SC at different positions in the Z direction. As described above, the present embodiment is not limited to alignment in the X direction and the Y direction. For example, a relative positional shift in the Z direction may be obtained in the first measurement, and the substrate 73 may be aligned in the Z direction so as to place the mark image 72A at the focal position of the image capturing device 50 in the second measurement based on the result of the first measurement.

A method of setting measurement parameters in the first measurement and the second measurement will be described subsequently. As described above, in a case where different binning conditions are set in the first measurement and the second measurement, since output data from the image capturing element 75 differ in signal intensity and pixel count, setting the same measurement parameter may cause a deterioration in measurement accuracy.

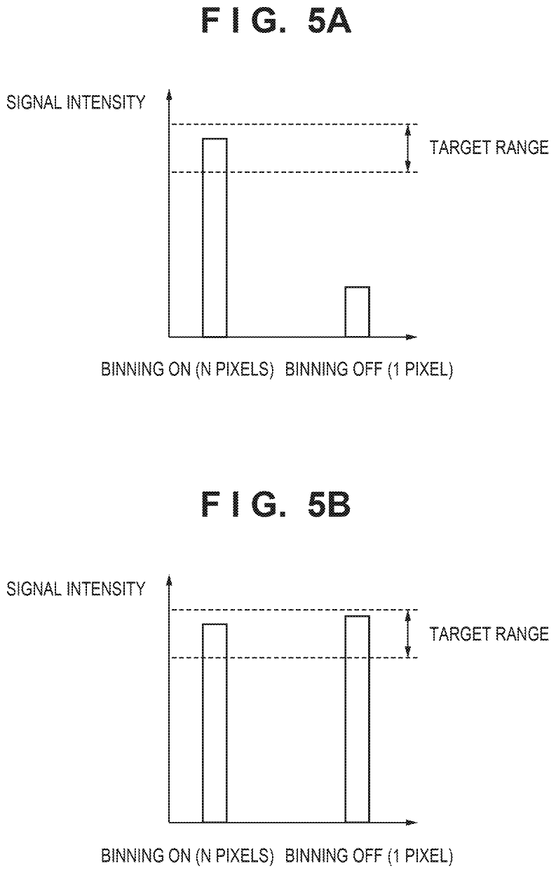

FIGS. 5A and 5B show examples of the signal intensities detected by the image capturing element 75 and the target ranges of signal intensities in a case where different binning conditions are set in the first measurement and the second measurement. FIGS. 5A and 5B respectively show cases where the same measurement parameter is set in the first measurement and the second measurement and different measurement parameters are set in the first measurement and the second measurement. If the binning coefficient in the first measurement is set to N, and the binning coefficient in the second measurement is set to 1, the signal intensity in the case of binning ON (N pixels) becomes higher than in the case of binning OFF (1 pixel) in terms of the principle of binning processing. For this reason, as shown in FIG. 5A, in a case where the same measurement parameter is set, it is difficult for the signal intensity to fall within the target range under both the first binning condition and the second binning condition. Assume that in the case where measurement is performed with a signal intensity lower than a target signal intensity, the ratio of noise to the signal intensity increases, resulting in a deterioration in measurement accuracy. In a case where measurement parameters are adjusted to make the signal intensity fall within the target range based on the detected signal intensity, the measurement time increases, resulting in a deterioration in productivity.

The control unit CU sets measurement parameters in the first measurement and the second measurement such that both the signal intensity detected by the image capturing element in the first measurement (the first binning condition is set in the first measurement) and the signal intensity detected by the image capturing element in the second measurement (the second binning condition is set in the second measurement) fall within a target range. FIG. 5B shows the signal intensities detected in a case where different accumulation times of the image capturing element 75 are set. For example, the control unit CU sets a longer accumulation time in the second measurement than in the first measurement based on the number of pixels added by binning processing. With this setting, the signal intensities respectively detected in the first measurement and the second measurement in which different binning conditions are set can be made to fall within the target range.

Note that a measurement parameter is not limited to the accumulation time of the image capturing element 75. For example, a measurement parameter may be at least any of the gain of the image capturing element 75, the light amount adjustment amount (transmittance) set by a light amount adjustment unit, the output of the light source 61, the optical magnification of the image capturing device 50, and the like. For example, the control unit CU may set at least any of the set value of the gain of the image capturing element 75, the ND filter of the light amount adjustment unit, and the current value of the light source 61 based on the ratio between the numbers of pixels added by binning processing such that the signal intensity falls within the target range. In addition, the signal intensity may be adjusted to fall within the target range by switching the optical magnification of the image capturing device 50 between coarse measurement and fine measurement.

In addition, as shown in FIGS. 4B and 4C, in a case where different binning conditions are set in the first measurement and the second measurement, since the number of pixels of output data from the image capturing element 75 differs, the relationship between each pixel and the signal intensity in the first measurement differs from that in the second measurement. For example, the number of pixels from an origin point 70 of the image capturing element 75 to the mark image 72A in binning processing (2 pixels×2 pixels) is reduced to half of that in binning processing (1 pixel×1 pixel). For this reason, if the position of the mark 72 is calculated by using the same model signal (template) in the first measurement and the second measurement, the measurement accuracy deteriorates due to the difference between the number of pixels of the acquired signal and that of the template.

Accordingly, in the present embodiment, the control unit CU sets different templates in the first measurement and the second measurement based on the numbers of pixels of output data corresponding to binning conditions. For example, based on the different binning conditions set for coarse measurement and fine measurement in step S301, templates suitable for the numbers of pixels of the respective output data are set, and the coarse measurement in step S304 and the fine measurement in step S308 are performed. This makes it possible to prevent a deterioration in mark measurement accuracy due to the difference between the numbers of pixels of the acquired signal and the template.

Measurement parameter settings are not limited to templates, and at least any of a readout region in the image capturing element 75, gray level, and a processing algorithm may be set to different settings in the first measurement and the second measurement in accordance with at least any of a required measurement time, a measurement region, and measurement accuracy. For example, the gray level at the time of detection by the image capturing element 75 in coarse measurement may be reduced as compared with fine measurement to reduce the data capacity and shorten the transfer time. In addition, the operation time may be shortened by simplifying the arithmetic processing of calculating a mark position. In addition, the control unit CU may set the processing algorithm for processing images or signal waveforms to different settings in coarse measurement and fine measurement at the time of calculating a mark position. In addition, in order to suppress an increase in transfer time or operation time, a readout region of the image capturing element 75 in fine measurement may be reduced as compared with coarse measurement.

The case where the position of the same mark is measured in coarse measurement and fine measurement has been exemplified, but the application range of the present disclosure is not limited thereto. For example, as marks used in coarse measurement and fine measurement, marks differing in positions on a substrate, mark designs, or layers on which the marks are formed may be used. In this case, if the mark used in the first measurement and the mark used in the second measurement are respectively defined as the first mark and the second mark, the control unit CU acquires the relative position information of the first mark and the second mark in advance. The control unit CU calculates a position correction amount in step S305 based on the result of the first measurement executed in step S304 in FIG. 2 and the relative position information of the first mark and the second mark. In step S306, the control unit CU aligns the second mark with the measurement region of the image capturing element 75.

As described above, in the first embodiment, the control unit CU determines the first binning condition and the second binning condition based on the design information of the mark formed on a substrate. The control unit CU performs the first measurement of obtaining the position of the mark upon setting the first binning condition, obtains the position correction amount of the substrate based on the result of the first measurement, and aligns the substrate. Thereafter, the control unit CU performs the second measurement of obtaining the position of the mark upon setting the second binning condition and acquires the position information of the substrate. This makes it possible to measure a measurement target fast and accurately.

### Second Embodiment

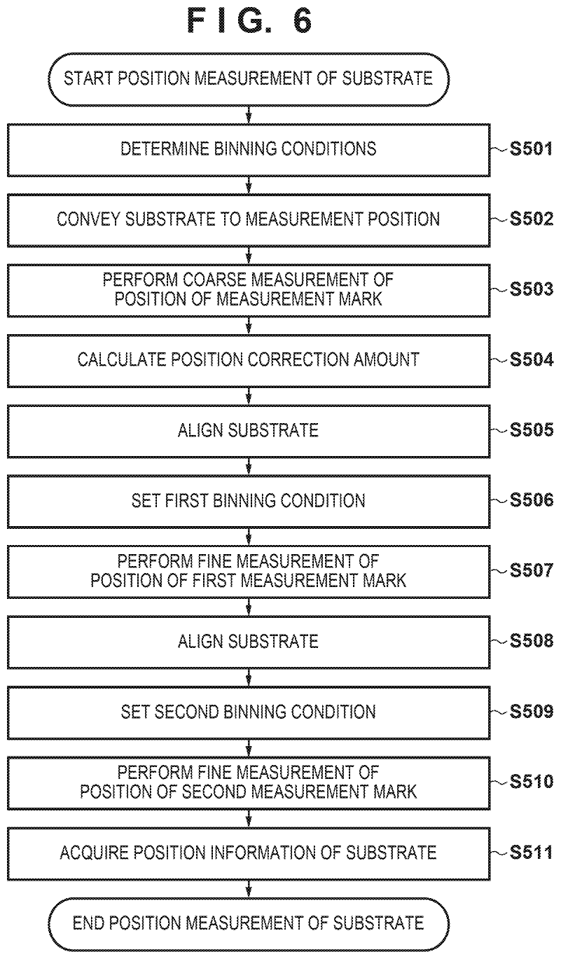

Measurement processing according to the second embodiment will be described with reference to FIG. 6. In the first embodiment, a position correction amount is obtained by performing coarse measurement in the first measurement. In contrast to this, in the second embodiment, the position information of the substrate is acquired by performing fine measurement in both the first measurement and the second measurement in which different binning conditions are set. Since the present embodiment differs from the first embodiment in their measurement processing sequences, the measurement processing sequences will be described in detail. Other contents are the same as those in the first embodiment, and hence a description thereof will be omitted.

FIG. 6 is a flowchart showing a measurement method according to the second embodiment. A control unit CU performs the measurement method (measurement processing) by comprehensively controlling the respective components of a measurement apparatus 100.

In step S501, the control unit CU determines a condition (first binning condition) concerning binning processing in the first measurement of measuring the position of a mark 72 and a condition (second binning condition) concerning binning processing in the second measurement based on the design information of the mark 72. In the present embodiment, after the execution of coarse measurement of obtaining the relative positional shift of a substrate 73 with respect to an image capturing device 50, fine measurement of accurately obtaining the position of the mark is performed in the first measurement and the second measurement.

In step S502, the control unit CU controls a substrate stage WS to convey the substrate 73 into the measurement viewing field of the image capturing device 50. Since steps S503, S504, and S505 are the same as steps S304, S305, and S306 in FIG. 2, a description thereof will be omitted. In step S505, the control unit CU preferably drives the substrate stage WS so as to align the first mark on the substrate 73 with respect to the image capturing device 50.

In step S506, the control unit CU sets the first binning condition determined in step S501 with respect to the image capturing element 75.

In step S507, the control unit CU controls the image capturing device 50 to capture an image of the first mark on the substrate 73. Thereafter, the control unit CU obtains the position of the first mark by performing image processing (signal processing and arithmetic processing) with respect to the image of the first mark obtained by image capturing.

In step S508, the control unit CU performs alignment to position the second mark in the measurement viewing field of the image capturing device 50 for the purpose of obtaining the position of the second mark placed at a position different from that of the first mark.

In step S509, the control unit CU sets the second binning condition determined in step S501 with respect to an image capturing element 75. In the present embodiment, the start of step S509 is not limited to a timing after the execution of step S508. For example, steps S508 and S509 may be concurrently executed.

In step S510, the control unit CU captures an image of the second mark on the substrate 73 by controlling the image capturing device 50. Thereafter, the control unit CU obtains the position of the second mark by performing image processing (signal processing and arithmetic processing) with respect to the image of the second mark obtained by image capturing.

In step S511, the control unit CU acquires the position information of the substrate 73 with respect to the image capturing device 50 based on the position of the first mark obtained in step S507 and the position of the second mark obtained in step S510.

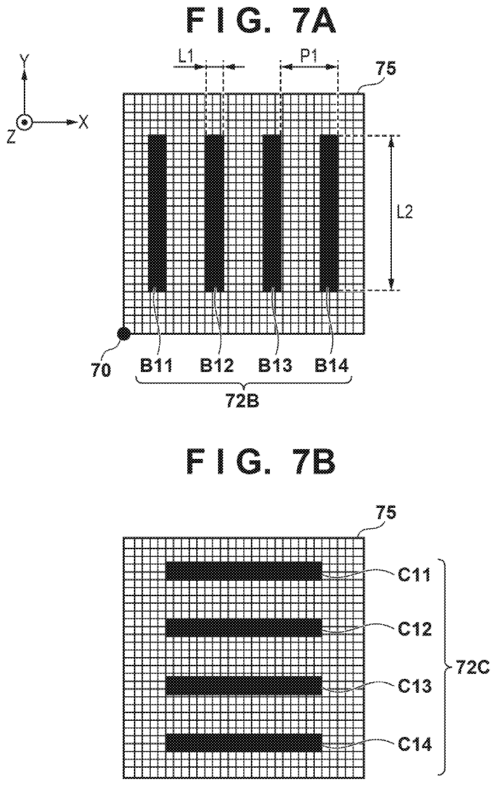

A method of performing fine measurement of the position of the substrate 73 by using the first mark and the second mark will be described with reference to FIGS. 7A and 7B. FIG. 7A shows an image of a first mark 72B formed on the detection surface of the image capturing element 75. The first mark 72B is configured as a mark pattern including a plurality of line elements B11, B12, B13, and B14 extending in the Y direction (first direction) corresponding to the vertical transfer direction of the image capturing element 75. The plurality of line elements B11, B12, B13, and B14 are arranged at an equal pitch P1, and each line element has a linewidth L1 and a length L2 in the Y direction. The first mark 72B is used for the purpose of accurately measuring the position of a substrate in the X direction. FIG. 7B shows a second mark 72C formed on the detection surface of the image capturing element 75. The second mark 72C is configured as a mark pattern including a plurality of line elements C11, C12, C13, and C14 extending in the X direction (the second direction intersecting the first direction) corresponding to the horizontal transfer direction of the image capturing element 75. The plurality of line elements C11, C12, C13, and C14 are arranged at the equal pitch P1, and each line element has the linewidth L1 and the length L2 in the Y direction. The second mark 72C is used for the purpose of accurately measuring the position of the substrate in the Y direction.

In the present embodiment, the first measurement is the measurement of th first mark 72B using the image capturing device 50, and the second measurement is the measurement of the second mark 72C using the image capturing device 50. As in the first embodiment, the control unit CU respectively determines binning conditions in the first measurement and the second measurement based on the design information of the first mark 72B and the design information of the second mark 72C on the substrate. A method of setting binning condition is the same in contents as those described in the first embodiment, and hence a description thereof will be omitted.

In addition, in the present embodiment, the first binning condition includes the first binning coefficient indicating the number of adjacent pixels subjected to binning in the Y direction and the second binning coefficient indicating the number of adjacent pixels subjected to binning in the X direction. In the measurement (first measurement) of the first mark 72B, performing binning processing in the Y direction of the first mark 72B makes it possible to satisfy requirements for both a shorter measurement time accompanying binning processing and a higher resolution in the measurement direction (X direction). In the measurement (second measurement) of the second mark 72C, performing binning processing in the X direction of the second mark 72C makes it possible to satisfy requirements for both a shorter measurement time accompanying binning processing and a higher resolution in the measurement direction (Y direction). Accordingly, in binning processing in the first measurement and the second measurement, a different condition is set in at least one of the horizontal transfer direction and the vertical transfer direction of the image capturing element 75.

As described above, in the second embodiment, the first binning condition and the second binning condition are determined based on the design information of the mark formed on the substrate. The position information of the substrate is obtained by performing the first measurement of measuring the first mark on the substrate under the first binning condition and the second measurement of measuring the second mark arranged at a position different from that of the first mark on the substrate under the second binning condition. This makes it possible to measure a measurement target fast and accurately.

### Third Embodiment

Measurement processing according to the third embodiment will be described next. The present embodiment is the same as the second embodiment in that fine measurement is performed by the first measurement and the second measurement in which different binning conditions are set. Since the present embodiment differs from the second embodiment in their measurement processing sequences, the measurement processing sequence will be described in detail below. Other contents are the same as those in the second embodiment, and hence a description thereof will be omitted.

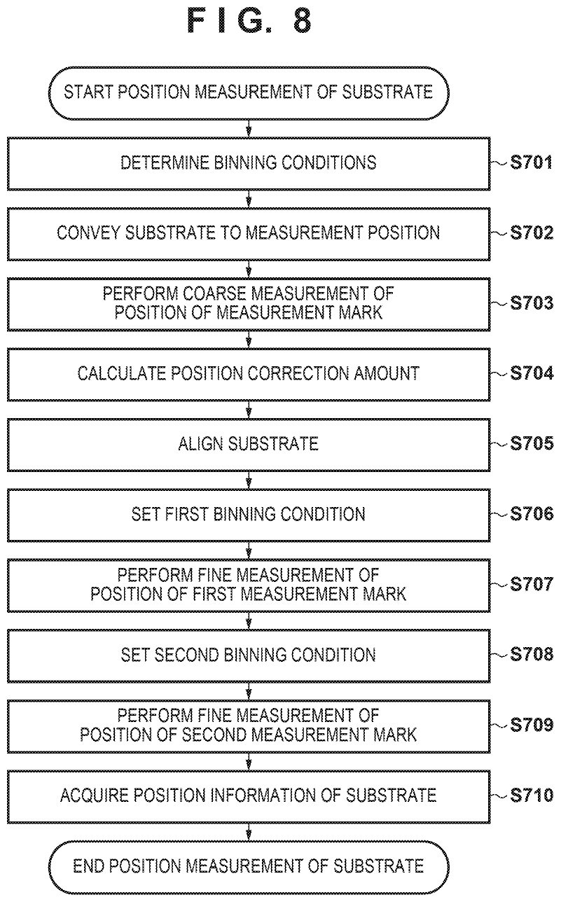

FIG. 8 is a flowchart of a measurement method according to the third embodiment. A control unit CU performs the measurement method (measurement processing) by comprehensively controlling the respective units of a measurement apparatus 100.

Steps S701 to S707 and steps S708 to S710 are the same as steps S501 S507 and steps S509 to S511 in FIG. 6. In the second embodiment, after the first measurement of measuring the first mark, the second mark placed at a position different from that of the first mark on the substrate 73 is aligned with the image capturing device 50. In contrast to this, in the present embodiment, after the first measurement is executed in step S707, the second measurement is performed in step S709 without alignment of the substrate.

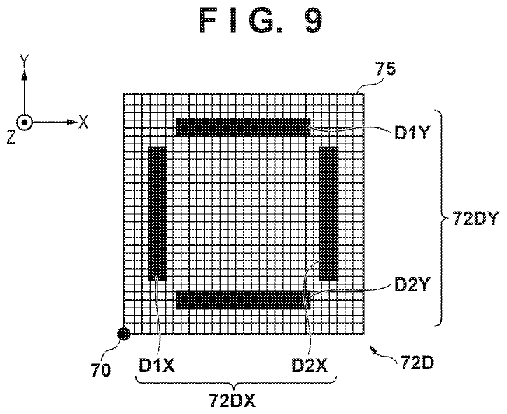

A method of performing fine measurement of the position of the substrate 73 by using the first mark and the second mark will be described with reference to FIG. 9. FIG. 9 shows an image of a mark 72D formed on the detection surface of an image capturing element 75. The mark 72D includes a plurality of first line elements 72DX extending in the Y direction corresponding to the vertical transfer direction of the image capturing element 75 and a plurality of second line elements 72DY extending in the X direction corresponding to the horizontal transfer direction of the image capturing element 75. In the case shown in FIG. 9, the plurality of first line elements 72DX include two line elements D1X and D2X for the accurate measurement of a position in the X direction. The plurality of second line elements 72DY include two line elements D1Y and D2Y for the accurate measurement of a position in the Y direction. The mark 72D is an example of a mark that enables the simultaneous measurement of positions in the X direction and the Y direction.

In the present embodiment, the first measurement is the measurement of th plurality of first line elements 72DX using the image capturing device 50, and the second measurement is the measurement of the plurality of second line elements 72DY using the image capturing device 50. A control unit CU determines different binning conditions in the first measurement and the second measurement as fine measurements based on the design information of the mark 72D including the plurality of first line elements 72DX and the plurality of second line elements 72DY. A method of setting binning conditions is the same as that in the second embodiment, and hence a description thereof will be omitted.

In the present embodiment, in fine measurement, the control unit CU executes the first measurement of measuring the plurality of first line elements 72DX upon setting the first binning condition and then executes the second measurement of measuring the plurality of second line elements 72DY upon setting the second binning condition. Performing the second measurement after the first measurement without performing alignment of the substrate in this manner can shorten the measurement time as compared with the second embodiment.

### Fourth Embodiment

Measurement processing according to the fourth embodiment will be described next. The present embodiment is the same as the third embodiment in that fine measurement is performed by the first measurement and the second measurement in which different binning conditions are set. Since the present embodiment differs from the third embodiment in their measurement processing sequences, the measurement processing sequence will be described in detail below. Other contents are the same as those in the third embodiment, and hence a description thereof will be omitted.

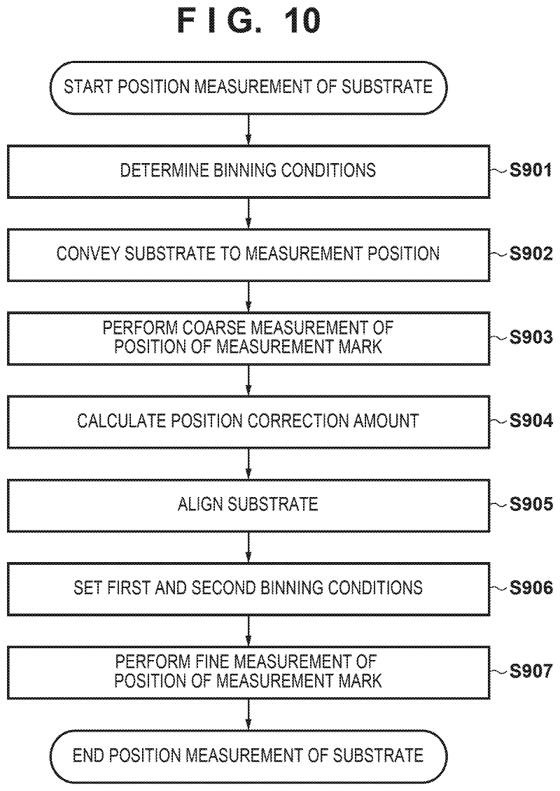

FIG. 10 is a flowchart of a measurement method according to the fourth embodiment. A control unit CU performs the measurement method (measurement processing) by comprehensively controlling the respective units of a measurement apparatus 100.

Steps S901 to S905 are the same as steps S701 to S705 in FIG. 8, and hence a description thereof will be omitted. In the third embodiment, the position information of the substrate 73 is acquired by performing the first measurement and the second measurement in which different binning conditions are respectively set with respect to the plurality of first line elements 72DX and the plurality of first line elements 72DY shown in FIG. 9. In contrast to this, in the present embodiment, in step S906, the control unit CU respectively sets the first measurement region in which the first binning condition is set with respect to the detection surface of an image capturing element 75 and the second measurement region in which the second binning condition is set. For example, the first measurement region is a measurement region of the image capturing element 75 which includes a plurality of first line elements 72DX that enable measurement in the X direction shown in FIG. 9, and the second measurement region is a measurement region of the image capturing element 75 which includes a plurality of first line elements 72DY that enable measurement in the Y direction. In step S907, the control unit CU simultaneously measures the position of the mark in the first measurement region and the second measurement region.

In the present embodiment, the control unit CU determines different binning conditions with respect to the first measurement and the second measurement as fine measurements based on the design information of the mark 72D including the plurality of first line elements 72DX and the plurality of first line elements 72DY. The first measurement and the second measurement are executed so as to simultaneously measure the position of the mark 72D in the first measurement region and the second measurement region on the detection surface of the image capturing element 75. This makes it possible to shorten the measurement time as compared with the third embodiment in which the second measurement is performed after the first measurement.

### Fifth Embodiment

The measurement apparatus described above can be used for the alignment of a substrate in a lithography apparatus such as an exposure apparatus or imprint apparatus. An example of applying the measurement apparatus according to the present disclosure to an exposure apparatus as an example of a lithography apparatus will be described.

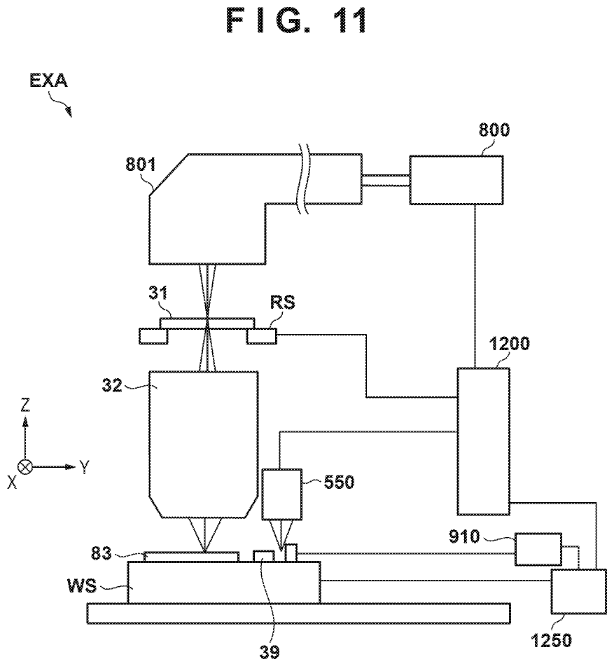

FIG. 11 is a schematic view showing the arrangement of an exposure apparatus EXA. The exposure apparatus EXA is a lithography apparatus which is used in a lithography process as a manufacturing process of a device such as a semiconductor device or a liquid crystal display device and forms a pattern on a substrate 83. The exposure apparatus EXA exposes the substrate 83 via a reticle 31 serving as an original, thereby transferring the pattern of the reticle 31 to the substrate 83. In this embodiment, the exposure apparatus EXA employs a step-and-scan method, but it can also employ a step-and-repeat method or other exposure methods.

As shown in FIG. 11, the exposure apparatus EXA includes an illumination optical system 801, a reticle stage RS which holds the reticle 31, a projection optical system 32, a substrate stage WS which holds the substrate 83, a position measurement apparatus 550, and a control unit 1200.

The illumination optical system 801 is an optical system that illuminates an illuminated surface using light from a light source unit 800. The light source unit 800 includes, for example, a laser. The laser includes an ArF excimer laser having a wavelength of about 193 nm, a KrF excimer laser having a wavelength of about 248 nm, or the like, but the type of light source is not limited to the excimer laser. For example, the light source unit 800 may use, as the light source, an F2 laser having a wavelength of about 157 nm or Extreme Ultraviolet (EUV) having a wavelength of 20 nm or less.

In this embodiment, the illumination optical system 801 shapes the light from the light source unit 800 into slit light having a predetermined shape suitable for exposure, and illuminates the reticle 31. The illumination optical system 801 has a function of uniformly illuminating the reticle 31 and a polarizing illumination function. The illumination optical system 801 includes, for example, a lens, a mirror, an optical integrator, a stop, and the like, and is formed by arranging a condenser lens, a fly-eye lens, an aperture stop, a condenser lens, a slit, and an imaging optical system in this order.

The reticle 31 is formed of, for example, quartz. The reticle 31 is formed with a pattern (circuit pattern) to be transferred to the substrate 83.

The reticle stage RS holds the reticle 31 via a reticle chuck (not shown), and is connected to a reticle driving mechanism (not shown). The reticle driving mechanism includes a linear motor or the like, and can move the reticle 31 held by the reticle stage RS by driving the reticle stage RS in the X-axis direction, the Y-axis direction, the Z-axis direction, and the rotation directions around the respective axes. Note that the position of the reticle 31 is measured by a reticle position measuring unit of light oblique-incidence type (not shown), and the reticle 31 is arranged at a predetermined position via the reticle stage RS.

The projection optical system 32 is arranged so as to make its optical axis extend along the Z direction and has a function of imaging the light from an object plane in an image plane. In this embodiment, the projection optical system 32 projects the light (diffracted light) having passed through the pattern of the reticle 31 onto the substrate 83, thereby forming the image of the pattern of the reticle 31 on the substrate. As the projection optical system 32, an optical system formed from a plurality of lens elements, an optical system (catadioptric optical system) including a plurality of lens elements and at least one concave mirror, an optical system including a plurality of lens elements and at least one diffractive optical element such as kinoform, or the like is used.

A photoresist is applied onto the substrate 83. The substrate 83 is a processing target object to which the pattern of the reticle 31 is transferred, and can include a wafer, a liquid crystal substrate, or another type of substrate to be processed.

The substrate stage WS holds the substrate 83 via a substrate chuck (not shown), and is connected to a substrate driving mechanism (not shown). The substrate driving mechanism includes a linear motor or the like, and can move the substrate 83 held by the substrate stage WS by driving the substrate stage WS in the X-axis direction, the Y-axis direction, the Z-axis direction, and the rotation directions around the respective axes. Further, a reference plate 39 is provided on the substrate stage WS.

The position of the substrate stage WS is monitored by, for example, a 6-axis laser interferometer 910 or the like and can be driven in synchronism with the driving of the reticle stage RS via a stage control unit 1250 under the control of the control unit 1200.

The control unit 1200 is formed by a computer (information processing apparatus) including a CPU, a memory, and the like and, for example, operates the exposure apparatus EXA by comprehensively controlling respective units of the exposure apparatus EXA in accordance with a program stored in a storage unit. The control unit 1200 controls an exposure process of transferring the pattern of the reticle 31 to the substrate 83 by exposing the substrate 83 via the reticle 31. Further, in this embodiment, the control unit 1200 controls a measurement process in the position measurement apparatus 550 and a correction process (calculation processing) of a measurement value obtained by the position measurement apparatus 550. In this manner, the control unit 1200 also functions as a part of the position measurement apparatus 550.

In the exposure apparatus EXA, the light (diffracted light) having passed through the reticle 31 is projected onto the substrate 83 via the projection optical system 32. The reticle 31 and the substrate 83 are arranged in an optically conjugate relationship. The pattern of the reticle 31 is transferred to the substrate 83 by scanning the reticle 31 and the substrate 83 at a speed ratio of a reduction ratio of the projection optical system 32.

The position measurement apparatus 550 is a measurement apparatus for measuring the position of a target object. In the present embodiment, the position measurement apparatus 550 measures the positions of a plurality of different marks 82 such as alignment marks provided on the substrate 83. Note that the arrangement of the position measurement apparatus 550 is similar to the arrangement of the image capturing device 50 shown in FIG. 1B, so that a description thereof will be omitted here.

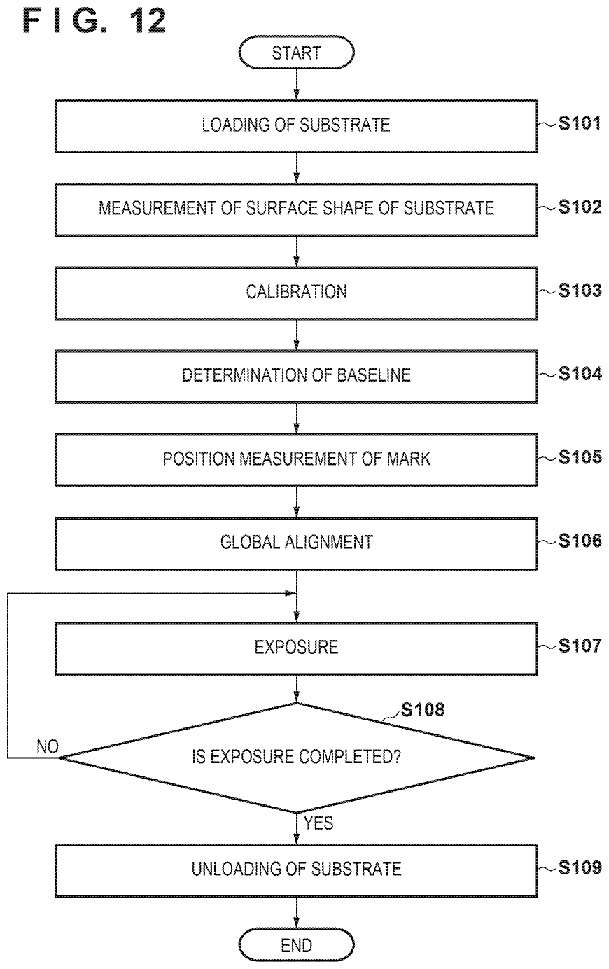

With reference to FIG. 12, the sequence of an exposure process of transferring the pattern of the reticle 31 onto the substrate 83 by exposing the substrate 83 via the reticle 31 will be described. As has been described above, the exposure process is performed by the control unit 1200 comprehensively controlling the respective units of the exposure apparatus EXA.

In step S101, the substrate 83 is loaded in the exposure apparatus EXA by a conveyance apparatus (not shown). In step S102, the surface (height) of the substrate 83 is detected by a shape measurement apparatus (not shown) to measure the surface shape of the entire substrate 83.

In step S103, calibration is performed. More specifically, based on the designed coordinate position of the reference mark provided in a reference plate 39 in the stage coordinate system, the control unit 1200 drives the substrate stage WS so as to position the reference mark on the optical axis of the position measurement apparatus 550. Then, the control unit 1200 measures the positional shift of the reference mark with respect to the optical axis of the position measurement apparatus 550, and the stage coordinate system is reset based on the positional shift such that the origin of the stage coordinate system coincides with the optical axis of the position measurement apparatus 550. Next, based on the designed positional relationship between the optical axis of the position measurement apparatus 550 and the optical axis of the projection optical system 32, the control unit 1200 drives the substrate stage WS so as to position the reference mark on the optical axis of the exposure light. Then, the control unit 1200 measures the positional shift of the reference mark with respect to the optical axis of the exposure light via the projection optical system 32 by using a TTL (Through The Lens) measurement system.

In step S104, based on the result of calibration obtained in step S103, the control unit 1200 determines the baseline between the optical axis of the position measurement apparatus 550 and the optical axis of the projection optical system 32. In step S105, the control unit 1200 controls the position measurement apparatus 550 to measure the position of the mark 82 provided on the substrate 83.

In step S106, the control unit 1200 performs global alignment. More specifically, based on the measurement result obtained in step S105, the control unit 1200 calculates the shift, the magnification, and the rotation with respect to the array of shot regions on the substrate 83 and obtains the regularity of the array of the shot regions. Then, the control unit 1200 obtains a correction coefficient from the regularity of the array of the shot regions and the baseline and aligns the substrate 83 with the reticle 31 (exposure light) based on the correction coefficient.

In step S107, the control unit 1200 executes exposure of the substrate 83 while scanning the reticle 31 and the substrate 83 in a scanning direction (Y direction). At this time, based on the surface shape of the substrate 83 measured by the shape measurement apparatus, the control unit 1200 also performs an operation of sequentially adjusting the surface of the substrate 83 to the imaging plane of the projection optical system 32 by driving the substrate stage WS in the Z direction and the tilt direction.

In step S108, the control unit 1200 determines whether exposure for all the shot regions of the substrate 83 is completed (that is, whether there is no unexposed shot region). If exposure for all the shot regions of the substrate 83 is not completed, the process returns to step S107, and steps S107 and S108 are repeated until exposure for all the shot regions is completed. On the other hand, if exposure for all the shot regions of the substrate 83 is completed, the process advances to step S109, and the substrate 83 is unloaded from the exposure apparatus EXA.

In the present embodiment, the measurement apparatus 100 according to any of the first to fourth embodiments is applied to the exposure apparatus EXA. More specifically, the position measurement apparatus 550 can include the image capturing device 50 shown in FIG. 1B. For example, the control unit 1200 can implement the function of the control unit CU described in the first to fourth embodiments.

In the present embodiment, the position measurement apparatus 550 (that is, the image capturing device 50) includes a plurality of pixels that detect light from a mark and forms an image capturing region for capturing an image of the mark using a plurality of pixels. The control unit 1200 obtains the position of the mark based on an output from the image capturing device 50 upon binning processing. The control unit 1200 executes measurement processing in accordance with any of the first to fourth embodiments. More specifically, the control unit 1200 determines binning conditions based on the design information of the mark and performs the first measurement of obtaining the position of the mark upon setting the first binning condition and the second measurement of obtaining the position of the mark upon setting the second binning condition different from the first binning condition. The control unit 1200 obtains the position of the substrate based on the results of the first measurement and the second measurement or the result of the second measurement. This makes it possible to accurately measure the measurement target.

### Embodiment of Article Manufacturing Method

An article manufacturing method according to an embodiment of the present disclosure is suitable for manufacturing an article, for example, a microdevice such as a semiconductor device or an element having a microstructure. The article manufacturing method according to the present embodiment includes a step of transferring the pattern of an original plate onto a substrate by using the above lithography apparatus (for example, an exposure apparatus or a drawing apparatus) and a step of processing the substrate onto which the pattern is transferred in the transferring step. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

According to the present disclosure, it is possible to provide a measurement apparatus advantageous in implementing high measurement accuracy in, for example, mark measurement using a binning function.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

1. A measurement apparatus that measures a position of a mark provided on a substrate, the apparatus comprising:
an image capturing device configured to capture an image of the mark by using an image capturing element; and
a control unit configured to obtain a position of the mark based on a result of first measurement using the image capturing device and a result of second measurement using the image capturing device which is performed after the first measurement,
wherein the control unit determines, based on design information of the mark, a first binning condition as a condition concerning binning processing in the first measurement and a second binning condition as a condition concerning binning processing in the second measurement,
performs the first measurement upon setting the first binning condition, and
performs the second measurement upon setting the second binning condition

2. The measurement apparatus according to claim 1, wherein the first measurement and the second measurement are respectively coarse measurement of a relative positional shift of the substrate with respect to the image capturing device and fine measurement of the relative positional shift,
the first binning condition and the second binning condition respectively include binning coefficients indicating the numbers of adjacent pixels subjected to binning, and
the control unit determines the first binning condition and the second binning condition such that a binning coefficient designated by the first binning condition becomes larger than a binning coefficient designated by the second binning condition.

3. The measurement apparatus according to claim 2, wherein the mark is constituted by a plurality of line elements extending in a first direction corresponding to a vertical transfer direction of the image capturing element,
the design information includes information concerning a linewidth of a lin element, a pitch between line elements, and a length of the line element in the first direction, and
letting, on a detection surface of the image capturing element, L1 be the linewidth, P1 be the pitch, L2 be the length, Ps be a pixel size of the image capturing element, and N be the binning coefficient, the control unit determines the binning coefficient designated by the first binning condition so as to satisfy
N≤L1/Ps
N≤P1/Ps
N≤L2/Ps.

4. The measurement apparatus according to claim 2, wherein the mark is constituted by a plurality of line elements extending in a first direction corresponding to a vertical transfer direction of the image capturing element,
the design information includes information concerning a linewidth of a lin element, a pitch between line elements, and a length of the line element in the first direction,
the binning coefficient includes a first binning coefficient indicating the number of adjacent pixels subjected to binning in the first direction and a second binning coefficient indicating the number of adjacent pixels subjected to binning in a second direction corresponding to a horizontal transfer direction of the image capturing element, and
letting, on a detection surface of the image capturing element, L1 be the linewidth, P1 be the pitch, L2 be the length, Ps be a pixel size of the image capturing element, Ny be the first binning coefficient, and Nx be the second binning coefficient, the control unit determines the first binning coefficient designated by the first binning condition and the second binning coefficient so as to satisfy
Nx≤L1/Ps
Nx≤P1/Ps
Ny≤L2/Ps.

5. The measurement apparatus according to claim 3, wherein letting Pi be a maximum signal intensity that can be detected by the image capturing element and Si be a signal intensity that enables measurement of the mark with required accuracy, the control unit determines the binning coefficient designated by the first binning condition so as to satisfy
N≤Pi/Si.

6. The measurement apparatus according to claim 1, wherein the control unit sets a measurement parameter in the first measurement or the second measurement such that both a signal intensity detected by the image capturing element in the first measurement in which the first binning condition is set and a signal intensity detected by the image capturing element in the second measurement in which the second binning condition is set fall within a target range.

7. The measurement apparatus according to claim 6, wherein the measurement parameter is an accumulation time of the image capturing element.

8. The apparatus according to claim 6, further comprising:
a light source;
an illumination optical system configured to illuminate the substrate with light from the light source; and
a light amount adjustment unit configured to adjust an amount of light illuminating the substrate by the illumination optical system,
wherein the measurement parameter is at least any of an accumulation time of the image capturing element, a gain of the image capturing element, a light amount adjustment amount by the light amount adjustment unit, an output of the light source, and an optical magnification of the image capturing device.

9. The measurement apparatus according to claim 1, further comprising a substrate stage configured to hold and move the substrate,
wherein the control unit performs the first measurement in which the first binning condition is set, controls the substrate stage based on a result of the first measurement so as to align the substrate with respect to the image capturing device, and then performs the second measurement in which the second binning condition is set.

10. The measurement apparatus according to claim 1, wherein the mark includes a first mark constituted by a plurality of line elements extending in a first direction corresponding to a vertical transfer direction of the image capturing element and a second mark constituted by a plurality of line elements extending in a second direction corresponding to a horizontal transfer direction of the image capturing element,
the first measurement and the second measurement are respectively measurement of the first mark using the image capturing device and measurement of the second mark using the image capturing device, and
the first binning condition and the second binning condition respectively include a first binning coefficient indicating the number of adjacent pixels subjected to binning in the first direction and a second binning coefficient indicating the number of adjacent pixels subjected to binning in the second direction.

11. The measurement apparatus according to claim 1, wherein the mark includes a plurality of first line elements extending in a first direction corresponding to a vertical transfer direction of the image capturing element and a plurality of second line elements extending in a second direction corresponding to a horizontal transfer direction of the image capturing element,
the first measurement and the second measurement are respectively measurement of the plurality of first line elements using the image capturing device and measurement of the plurality of second line elements using the image capturing device, and
the first binning condition and the second binning condition respectively include a first binning coefficient indicating the number of adjacent pixels subjected to binning in the first direction and a second binning coefficient indicating the number of adjacent pixels subjected to binning in the second direction.

12. The measurement apparatus according to claim 1, wherein the mark includes a plurality of first line elements extending in a first direction corresponding to a vertical transfer direction of the image capturing element and a plurality of second line elements extending in a second direction corresponding to a horizontal transfer direction of the image capturing element, and
the control unit sets a first measurement region in which the first binning condition is set with respect to a detection surface of the image capturing element and a second measurement region in which the second binning condition is set with respect to the detection surface,
performs measurement of the plurality of first line elements using the first measurement region as the first measurement, and
performs measurement of the plurality of second line elements using the second measurement region as the second measurement.

13. The measurement apparatus according to claim 1, wherein the mark includes a first mark comprising a plurality of line elements extending in a first direction and a second mark comprising a plurality of line elements extending in a second direction different from the first direction, and
the control unit performs the measurement of the mark by setting a binning condition in a measurement of the first mark and a binning condition in a measurement of the second mark to be different from each other.

14. A measurement method of measuring a position of a mark provided on a substrate based on a result of first measurement using an image capturing device configured to capture an image of the mark and a result of second measurement using the image capturing device which is performed after the first measurement, the method comprising:
determining, based on design information of the mark, a first binning condition as a condition concerning binning processing in the first measurement and a second binning condition as a condition concerning binning processing in the second measurement;
performing the first measurement upon setting the first binning condition; and
performing the second measurement upon setting the second binning condition.

15. A lithography apparatus that forms a pattern on a substrate, the apparatus comprising:
a measurement apparatus defined in claim 1 and configured to measure a position of a mark provided on a substrate; and
a positioning mechanism configured to position the substrate based on a position of the mark measured by using the measurement apparatus.

16. An article manufacturing method comprising:
forming a pattern on a substrate by using a lithography apparatus defined in claim 15; and
processing the substrate on which the pattern is formed,
wherein an article is manufactured from the processed substrate.
